(19) United States
(12) Patent Application Publication
(10) Pub. No.: US 2026/0181782 A1
(43) Pub. Date: Jun. 25, 2026

(54) ARRANGEMENT WITH A PRINTED CIRCUIT BOARD AND A CIRCUIT FOR DETECTING CARBONIZATION OF THE PRINTED CIRCUIT BOARD

(71) Applicant: HELLA GmbH & Co. KGaA, Lippstadt (DE)

(72) Inventor: Manfred FUISTING, Warendorf (DE)

(73) Assignee: HELLA GmbH & Co. KGaA, Lippstadt (DE)

(21) Appl. No.: 19/428,182

(22) Filed: Dec. 20, 2025

(30) Foreign Application Priority Data
Dec. 20, 2024 (DE) 10 2024 139 264.9

(51) Int. Cl. H05K 1/181; G01R 19/165; G01R 19/25

(52) U.S. Cl. CPC H05K 1/181; G01R 19/16533; G01R 19/25; H05K 2201/10151

(57) ABSTRACT

An arrangement with a printed circuit board and to a circuit for detecting carbonization of the printed circuit board, wherein a control circuit for controlling a power circuit is provided on the printed circuit board and the control circuit has an input for supplying the control circuit with an operating voltage and the control circuit has an output to which the power circuit is connected or can be connected. The circuit for detecting carbonization has a current sensor, which is connected to the input of the control circuit for supplying the control circuit with an operating voltage. The current sensor has an output at which a signal is present which indicates the current strength of the current flowing through the input for supplying the control circuit, and has an evaluation circuit, which has an input which is connected to the output of the current sensor.

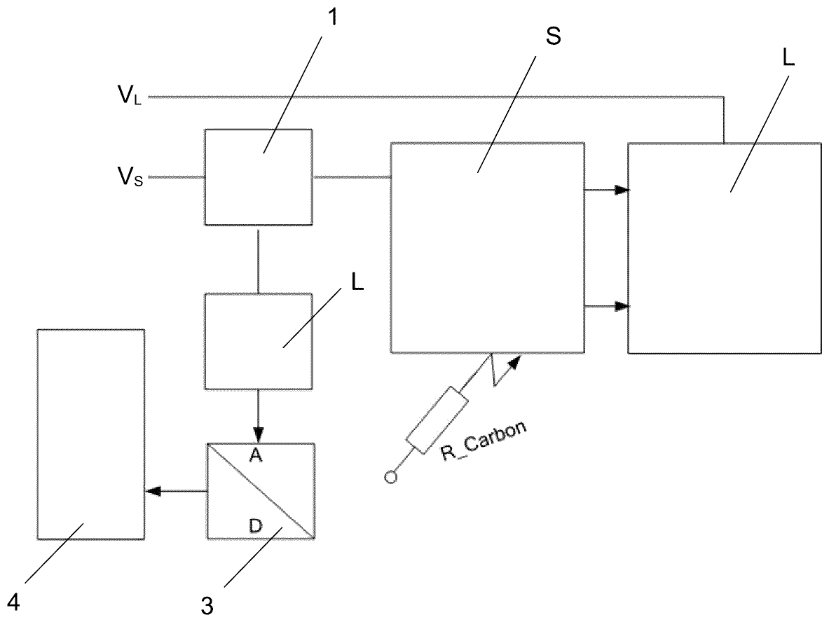

This nonprovisional application claims priority under 35 U.S.C. § 119(a) to German Patent Application No. 10 2024 139 264.9, which was filed in Germany on Dec. 20, 2024, and which is herein incorporated by reference.

### BACKGROUND OF THE INVENTION

### Field of the Invention

The invention relates to an arrangement with a printed circuit board and to a circuit for detecting carbonization of the printed circuit board, wherein a control circuit for controlling a power circuit is provided on the printed circuit board and the control circuit has an input for supplying the control circuit with an operating voltage and the control circuit has an output to which the power circuit is connected or can be connected.

### Description of the Background Art

Printed circuit boards are widely used. They are used to arrange circuits on them that are used to control functions, actuators, and sensors in the context of control units, machines, and devices.

High temperature inputs, which are above the specification, on a printed circuit board lead to aging and material degradation in the printed circuit board. Conductive carbon can form in this process. The conductive carbon can develop an electric arc when ignited (e.g., by a short circuit of neighboring conductor traces). Electric arcs develop extreme heat (>1000° C.). This can lead to further destruction of the printed circuit board or the electrical circuit for which the printed circuit board was used. Such arcs can only be interrupted by disconnecting the power supply. The object of the invention is to detect carbonization of the printed circuit board before an electric arc occurs.

A plastic circuit card with a carbonization sensor for protecting against electrical smoldering fires is known from document EP 1 615 483 A2, which corresponds to US 2006/0006878. The carbonization sensor comprises, as conductor track structures for detecting carbonization of the printed circuit board, first and second sensor conductor tracks, which are disposed on the circuit card and are part of the printed circuit board. In addition, the carbonization sensor comprises a monitoring device that can be disposed on the printed circuit board. The two sensor tracks are electrically insulated from one another by a plastic of the printed circuit board and the monitoring device monitors the insulating state of the two sensor tracks in relation to one another. It generates a fault signal when currents above a predetermined value flow between the two sensor tracks. Carbonization of the circuit card is detected at an early stage by the carbonization sensor, even before the carbonization, which makes the circuit card electrically conductive, leads to an electrical smoldering fire due to an avalanche effect.

The known solution and a very similar solution known from document US 2005/275552 A1 can detect carbonization if it leads to a change in the insulation or conductivity between the first and second traces. However, there may also be cases in which carbonization occurs at other points on the circuit card and not between the two sensor traces of the carbonization sensor. Thus, for example, carbonization can occur between traces other than the first and second sensor traces. This is even more likely, because local overheating resulting in carbonization often occurs in the vicinity of components that are connected via the other traces and not via the sensor traces.

A further solution is therefore sought as to how the carbonization of a printed circuit board can be detected.

### SUMMARY OF THE INVENTION

It is therefore an object of the present invention to provide a circuit for detecting carbonization.

In an example, the circuit has a current sensor, which is connected to the input of the control circuit for supplying the control circuit with an operating voltage, wherein the current sensor has an output at which a signal is present which indicates the current strength of the current flowing through the input for supplying the control circuit, and has an evaluation circuit, which has an input which is connected to the output of the current sensor, which is designed to evaluate the signal, present at the output of the current sensor, for the current strength of the current flowing through the input for supplying the control circuit in order to detect carbonization of the printed circuit board on the basis of the instantaneous current strength or the course of the current strength, which is designed to generate a warning signal when carbonization has been detected, and which has an output for displaying the warning signal.

In contrast to the technical teaching known from the aforementioned documents, in a printed circuit board of the invention, a change in the printed circuit board is not detected via special structures provided only for the detection of carbonization in a printed circuit board, but by evaluating the current picked up by the control circuit disposed on the printed circuit board. This current increases when carbonization of the printed circuit board occurs, because there is an additional current flow due to the carbonization. The additionally flowing current flows through the previously insulating circuit board parts which have become conductive due to the carbonization. This additional current or the change in the current consumption and/or in the course of the current consumption of the control circuit caused by this additional current can be detected by the circuit provided according to the invention for detecting the carbonization with the current sensor provided according to the invention and the evaluation circuit provided according to the invention. The evaluation circuit evaluates the current consumption and can detect carbonization in this way.

The evaluation circuit of an arrangement of the invention can be designed in such a way that, in order to detect carbonization, the instantaneous current strength is compared with a predetermined value, the course of the current strength is compared with a predetermined course, and the instantaneous current strength and/or the course of the current strength are evaluated by means of pattern matching, by means of an artificial neural network, and/or by means of other artificial intelligence methods.

The circuit for detecting the carbonization of a printed circuit board of an arrangement of the invention can have a filter provided between the output of the current sensor and the input of the evaluation circuit.

The circuit for detecting carbonization can have an A/D converter, which is provided between the output of the current sensor or the filter, on the one hand, and the input of the evaluation circuit, on the other.

The evaluation circuit can be an integrated circuit, in particular a microcontroller.

An arrangement of the invention can be a part of a control unit for a motor vehicle, in particular for a lighting system, an access system, for controlling the on-board electrical system, a radar system, a lidar system, etc.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWING

The present invention will become more fully understood from the detailed description given hereinbelow and the accompanying drawings which are given by way of illustration only, and thus, are not limitive of the present invention, and wherein the soled figure shows, in a schematic diagram, an arrangement formed of a control circuit, a power circuit, and a circuit for detecting the carbonization of a printed circuit board.

### DETAILED DESCRIPTION

Power circuit L shown in the figure is connected to a power supply (not shown) for the power circuit. Likewise, control circuit S is connected to a power supply, namely, to a power supply for control circuit S. Control circuit S and power circuit L are connected to each other so that control circuit S can control power circuit L.

A current sensor 1, which detects the current flowing from the power supply into the control circuit, is provided in a connection between the power supply for the control circuit and control circuit S. An analog signal representing the current is present at an output of current sensor 1. Current sensor 1 could comprise, for example, a resistor component. The voltage across this resistor component could be tapped and applied to the output of current sensor 1.

The signal present at the output of current sensor 1 and representing the current flowing into the control circuit, is filtered by means of a filter 2 in the case of the example shown and then converted into a digital signal by means of an analog-to-digital converter 3, which signal is fed to a microcontroller 4 that evaluates the signal.

Power circuit L, control circuit S, current sensor 1, filter 2, analog-to-digital converter 3, and microcontroller 4 are arranged on the circuit board, which is not shown in detail. Current sensor 1, filter 2, analog-to-digital converter 3, and microcontroller 4 form a circuit for detecting the carbonization of the printed circuit board.

To detect carbonization of the printed circuit board, the microcontroller compares the current measured by current sensor 1 with predefined values. If the current rises above the specified value, the cause can be carbonization of the printed circuit board, which, due to local heat development, for example, leads to the printed circuit board losing its insulating properties locally. This can result in a current flow across the conductive point R_Carbon of the printed circuit board, which leads to an increase in the current flowing into the control circuit, which can then be detected by microcontroller 4 and recognized as carbonization. Microcontroller 4 can then signal the carbonization to an output and generate a warning signal in addition.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An arrangement comprising:
a printed circuit board;
a circuit to detect carbonization of the printed circuit board; and
a control circuit to control a power circuit, the control circuit being provided on the printed circuit board, the control circuit having an input to supply the control circuit with an operating voltage and having an output to which the power circuit is adapted to be connected,
wherein, the circuit for detecting carbonization comprises:
a current sensor that is connected to the input of the control circuit to supply the control circuit with an operating voltage, the current sensor having an output at which a signal is present that indicates a current strength of the current flowing through the input to supply the control circuit; and
an evaluation circuit having an input that is connected to the output of the current sensor, that evaluation circuit evaluating the signal present at the output of the current sensor for the current strength of the current flowing through the input for supplying the control circuit in order to detect carbonization of the printed circuit board on the basis of an instantaneous current strength or the course of the current strength, the evaluation circuit generating a warning signal when carbonization has been detected, and has an output for displaying the warning signal.

2. The arrangement according to claim 1, wherein the evaluation circuit (4) is designed, in order to detect carbonization, to compare the instantaneous current strength with a predetermined value, to compare the course of the current strength with a predetermined course, and to evaluate the instantaneous current strength and/or the course of the current strength by means of pattern matching and/or by means of an artificial neural network or by means of other artificial intelligence methods.

3. The arrangement according to claim 1, wherein the circuit for detecting the carbonization has a filter provided between the output of the current sensor and the input of the evaluation circuit.

4. The arrangement according to claim 1, wherein the circuit for detecting carbonization has an A/D converter that is provided between the output of the current sensor or the filter and the input of the evaluation circuit.

5. The arrangement according to claim 1, wherein the evaluation circuit is an integrated circuit or a microcontroller.

6. The arrangement according to claim 1, wherein the power circuit is disposed on the circuit board.

7. A control unit for a motor vehicle or for a lighting system or an access system to control an on-board electrical system, a radar system, or a lidar system, wherein the control unit comprises the arrangement according to claim 1.
